(19) United States
(12) Patent Application Publication
(10) Pub. No.: US 2024/0429675 A1
(43) Pub. Date: Dec. 26, 2024

(54) FILM-EQUIPPED COMPONENT AND OPTICAL DEVICE

(71) Applicant: NIPPON ELECTRIC GLASS CO., LTD., Otsu-shi, Shiga (JP)

(72) Inventors: Hiroki FUJITA, Otsu-shi (JP); Hirokazu TANAKA, Otsu-shi (JP); Yoshimasa YAMAGUCHI, Otsu-shi (JP)

(21) Appl. No.: 18/684,240

(22) PCT Filed: Aug. 30, 2022
(86) PCT No.: PCT/JP2022/032558

§ 371 Date: Feb. 16, 2024

(30) Foreign Application Priority Data
Sep. 2, 2021 (JP) 2021-143435

(51) Int. Cl. H01S 5/023; H01S 5/02255; H01S 5/0236; H01S 5/024

(52) U.S. Cl. CPC H01S 5/023; H01S 5/02255; H01S 5/0236; H01S 5/02469

(57) ABSTRACT

Provided is a film-equipped component that, when subjected to a plurality of component mountings involving heating to melting, makes it less likely that any previously mounted component becomes misaligned. A film-equipped component 1 includes: a component main body 2; and an adhesion film 3 provided on a principal surface 2a of the component main body 2, wherein the adhesion film 3 includes: a Ni layer 6 layered directly or indirectly on the principal surface 2a of the component main body 2 and containing Ni; a diffusion suppressing layer 7 provided on the Ni layer 6; and a solder layer 8 provided on the diffusion suppressing layer 7 and containing at least one of Au and Sn.

### TECHNICAL FIELD

The present invention relates to film-equipped components and optical devices using the film-equipped components.

### BACKGROUND ART

Recently, optical devices mounted with an LD (laser diode), an LED (light-emitting diode) or like optical element have been used in displays, projectors, vehicle head lamps or other applications. In the optical devices, a component, such as an optical element, is fixed to a mounting substrate using a solder film. Among solder films, a solder film containing Au and Sn is known.

For example, Patent Literature 1 below discloses a method for bonding an optical semiconductor element onto a mounting substrate using an Au-Sn multilayered solder in which Au layers and Sn layers are alternately layered. In the Au-Sn multilayered solder of Patent Literature 1, a total of seven layers of Au and Sn are layered.

### CITATION LIST

### Patent Literature

[PTL 1]

JP-A-H10-006073

### SUMMARY OF INVENTION

### Technical Problem

Recently, in packaging using a component, such as an optical element, a large number of components have been increasingly mounted in a single package. However, if a solder film as in Patent Literature 1 is used to mount such a component and the mounting of a component involving heating to melting of the solder film is performed a number of times, the solder film for a component mounted in a first mounting may be melted again in second and later mountings. Thus, the component mounted in the first mounting may become misaligned, which arises a problem of being unable to sufficiently increase the reliability of the optical device.

As a method for solving the above problem, it is conceivable to use solder films having different melting points in decreasing order of melting point. However, this method has a problem of cumbersome material design and thus reduced productivity of the optical device.

An object of the present invention is to provide: a film-equipped component that, when subjected to a plurality of component mountings involving heating to melting, makes it less likely that any previously mounted component becomes misaligned; and an optical device using the film-equipped component.

### Solution to Problem

A description will be given below of aspects of a film-equipped component capable of solving the above problem and an optical device using the film-equipped component.

A film-equipped component according to Aspect 1 of the present invention includes: a component main body having a principal surface; and an adhesion film provided on the principal surface of the component main body, wherein the adhesion film includes: a Ni layer layered directly or indirectly on the principal surface of the component main body and containing Ni; a diffusion suppressing layer provided on the Ni layer; and a solder layer provided on the diffusion suppressing layer and containing at least one of Au and Sn.

A film-equipped component according to Aspect 2 is the film-equipped component according to Aspect 1, wherein a ratio of a thickness of the Ni layer to a thickness of the diffusion suppressing layer (thickness of Ni layer to thickness of diffusion suppressing layer) is preferably not less than 1 and not more than 600.

A film-equipped component according to Aspect 3 is the film-equipped component according to Aspect 1 or Aspect 2, wherein the diffusion suppressing layer preferably contains at least one selected from the group consisting of Ru, Rh, Pd, Os, Ir, and Pt.

A film-equipped component according to Aspect 4 is the film-equipped component according to any one of Aspects 1 to 3, wherein the diffusion suppressing layer more preferably contains Pt.

A film-equipped component according to Aspect 5 is the film-equipped component according to any one of Aspects 1 to 4, wherein the diffusion suppressing layer preferably has a thickness of 1000 nm or less.

A film-equipped component according to Aspect 6 is the film-equipped component according to any one of Aspects 1 to 5, wherein, preferably, the solder layer is bonded to a bonding object member to form a bonded solder layer, and in a direction of thickness of the bonded solder layer, a mass ratio (Au:Sn) between Au and Sn in a portion of the bonded solder layer close to the diffusion suppressing layer is 40:60 to 71:29 and a mass ratio (Au:Sn) between Au and Sn in a central portion of the bonded solder layer is 84:16 to 94:6.

A film-equipped component according to Aspect 7 is the film-equipped component according to any one of Aspects 1 to 6, wherein, preferably, the solder layer is bonded to a bonding object member to forma bonded solder layer and the bonded solder layer is composed of a region containing Au and Sn as major ingredients, a region containing Pt as a major ingredient, and a region containing Ni as a major ingredient in order closer to the bonding object member in a direction of thickness of the bonded solder layer. The term “major ingredient” means that the relevant material is contained 80% by mass or more in the region. Needless to say, the relevant material may be contained 100% by mass in the region. In other words, the region containing Au and Sn as major ingredients means a region where the total content of Au and Sn is 80% by mass or more. The same applies to the region containing Pt as a major ingredient and the region containing Ni as a major ingredient. Although ingredients of the bonding object member may be melted into the bonded solder layer, this is not considered.

A film-equipped component according to Aspect 8 is the film-equipped component according to any one of Aspects 1 to 6, wherein, preferably, the solder layer is bonded to a bonding object member to form a bonded solder layer and Ni is diffused into the bonded solder layer.

A film-equipped component according to Aspect 9 is the film-equipped component according to Aspect 7 or 8, wherein, preferably, the solder layer is bonded to a bonding object member to form a bonded solder layer and a content of Ni in the bonded solder layer has a concentration gradient in a direction of thickness of the bonded solder layer. The phrase “the content of Ni has a concentration gradient” means that the content of Ni in a region where Ni exists continuously increases or decreases. Although ingredients of the bonding object member may be melted into the bonded solder layer, this is not considered.

A film-equipped component according to Aspect 10 is the film-equipped component according to any one of Aspects 1 to 9 and is preferably at least one selected from the group consisting of a prism, a lens, an optical element, a sub-mount for use in mounting the optical element, a package for use in mounting the optical element, and a lid.

An optical device according to Aspect 11 of the present invention includes: a prism; an optical element that emits or receives light to or from the prism; a package where the prism and the optical element are mounted; and a sub-mount provided between the optical element and the package, wherein at least one of the prism and the sub-mount is the film-equipped component according to any one of Aspects 1 to 10.

### Advantageous Effects of Invention

The present invention enables provision of: a film-equipped component that, when subjected to a plurality of component mountings involving heating to melting, makes it less likely that any previously mounted component becomes misaligned; and an optical device using the film-equipped component.

### BRIEF DESCRIPTION OF DRAWINGS

FIG. 1 is a schematic cross-sectional view showing a film-equipped component according to a first embodiment of the present invention.

FIG. 2 is a schematic cross-sectional view showing in magnification a portion of the film-equipped component according to the first embodiment of the present invention where an adhesion film is provided.

FIG. 3 is a schematic cross-sectional view showing the adhesion film of the film-equipped component according to the first embodiment of the present invention after being heated to melting.

FIG. 4 is a schematic cross-sectional view showing a film-equipped component according to a second embodiment of the present invention.

FIG. 5(a) is a schematic plan view showing a film-equipped component according to a third embodiment of the present invention, FIG. 5(b) is a schematic cross-sectional view of a portion taken along the line A-A of FIG. 5(a), and FIG. 5(c) is a schematic cross-sectional view showing a modification of the portion.

FIG. 6 is a schematic cross-sectional view showing an optical device according to an embodiment of the present invention.

FIG. 7 is a graph showing an EDX spectrum of a portion of a bonded solder layer close to a diffusion suppressing layer in a film-equipped component obtained in Example 1.

FIG. 8 is a graph showing an EDX spectrum of a central portion of the bonded solder layer in the film-equipped component obtained in Example 1.

FIG. 9 is differential scanning calorimetry results of the film-equipped component obtained in Example 1.

FIG. 10 is differential scanning calorimetry results of a film-equipped component obtained in Example 2.

FIG. 11 is differential scanning calorimetry results of a film-equipped component obtained in Example 3.

FIG. 12 is differential scanning calorimetry results of a film-equipped component obtained in Example 4.

FIG. 13 is differential scanning calorimetry results of a film-equipped component obtained in Example 5.

FIG. 14 is differential scanning calorimetry results of a film-equipped component obtained in Comparative Example 1.

FIG. 15 is differential scanning calorimetry results of a film-equipped component obtained in Reference Example 1.

### DESCRIPTION OF EMBODIMENTS

Hereinafter, a description will be given of preferred embodiments. However, the following embodiments are merely illustrative and the present invention is not limited to the following embodiments. Throughout the drawings, members having substantially the same functions may be referred to by the same reference characters.

### Film-Equipped Component

### First Embodiment

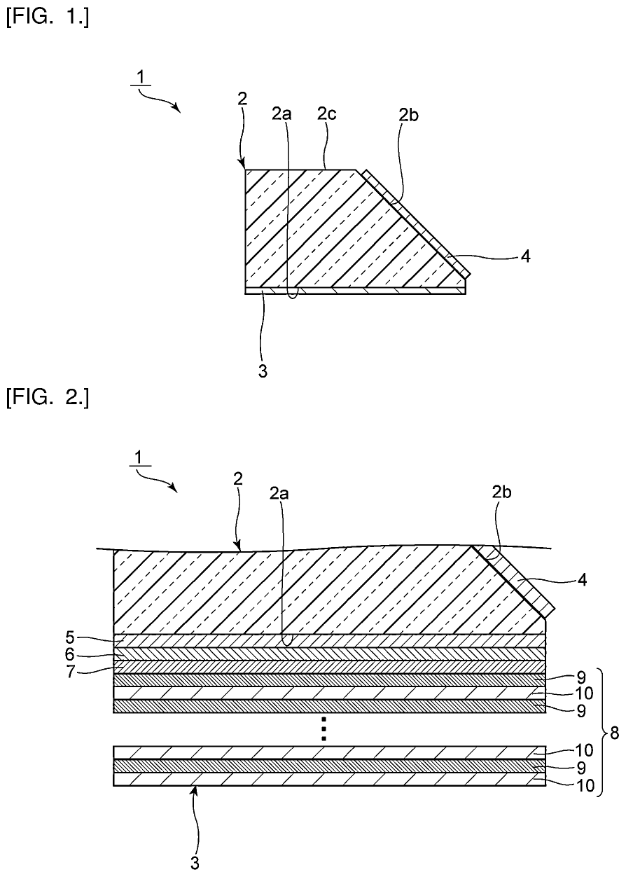

FIG. 1 is a schematic cross-sectional view showing a film-equipped component according to a first embodiment of the present invention. FIG. 2 is a schematic cross-sectional view showing in magnification a portion of the film-equipped component according to the first embodiment of the present invention where an adhesion film is provided.

A prism 1 is a film-equipped component for use in an optical device or an electronic device. The prism 1 includes a prism main body 2 as a component main body, an adhesion film 3, and a reflective film 4.

The prism main body 2 has an approximately trapezoidal cross-sectional shape. The prism main body 2 has a bottom surface 2a, an inclined surface 2b connected to the bottom surface 2a, and a top surface 2c opposed to the bottom surface 2a and connected to the inclined surface 2b. The cross-sectional shape of the prism main body 2 is not particularly limited and may be an approximately triangular shape or other shapes. In this embodiment, the prism main body 2 is made of an appropriate glass material.

The adhesion film 3 is provided on the bottom surface (principal surface) 2a of the prism main body 2. The prism 1 serving as the film-equipped component is fixed by the adhesion film 3 to a mounting substrate, a package or so on. The adhesion film 3 is provided preferably over the entire bottom surface 2a of the prism main body 2, but is sufficient to be provided at least partially on the bottom surface 2a of the prism main body 2. The adhesion film 3 may extend to the side surface of the prism main body 2. In this case, the wettability offered by the adhesion film 3 can be increased and, thus, the bonding strength can be further increased.

As shown in FIG. 2, the adhesion film 3 includes an underlying metal layer 5, a Ni layer 6, a diffusion suppressing layer 7, and a solder layer 8. The underlying metal layer 5 is layered directly on the prism main body 2. The Ni layer 6 is layered on the underlying metal layer 5. The diffusion suppressing layer 7 is layered on the Ni layer 6. The underlying metal layer 5, the Ni layer 6, and the diffusion suppressing layer 7 are so-called metallization layers. The solder layer 8 is layered on the diffusion suppressing layer 7 which is the outermost layer of the metallization layers.

Examples that can be used as a material constituting the underlying metal layer 5 include Cr, Ti, Ta, Ni, W, TiW, Mo, and Ni—Cr alloy. Among these materials, Cr, Ti or Ta is preferred. These materials may be used singly or in a combination of a plurality of them. It is desirable that the material constituting the underlying metal layer 5 includes any of the materials mentioned above as examples in an amount of 95% or more. However, the underlying metal layer 5 may contain impurities and additives without impairing the effects of the present invention.

The thickness of the underlying metal layer 5 is not particularly limited, but may be, for example, not less than 0.01 μm and not more than 0.50 μm. The underlying metal layer 5 can be formed by plating, vapor deposition, sputtering or other appropriate methods. The adhesion film 3 may not necessarily be provided with the underlying metal layer 5.

The Ni layer 6 is a layer containing Ni or a Ni-containing alloy as a major ingredient. An example of the Ni-containing alloy is Ni—Cr alloy. The term “major ingredient” herein means that the relevant material is contained 80% by mass or more in the Ni layer 6. Needless to say, the relevant material may be contained 100% by mass in the layer.

The Ni layer 6 can be formed by plating, vapor deposition, sputtering or other appropriate methods.

The diffusion suppressing layer 7 is a layer that retards the diffusion of Ni contained in the Ni layer 6 into the solder layer 8. While the adhesion film 3 is heated to melting, the ingredient of the Ni layer 6 diffuses into the solder layer 8 to be described hereinafter and so on. When the diffusion suppressing layer 7 is provided, the diffusion is retarded and, as a result, the amount of ingredient diffused can be reduced or adjusted. Thus, the meltability of the adhesion film 3 during an initial melting can be further increased, the wettability of the adhesion film 3 on the package or the like can be increased, and the initial bonding strength can be further increased.

The material for the diffusion suppressing layer 7 is not particularly limited, but it is Pt in this embodiment. In this case, the diffusion of Ni contained in the Ni layer 6 into the solder layer 8 can be further retarded and, as a result, the amount of Ni diffused can be reduced or adjusted. However, the material for the diffusion suppressing layer 7 is not limited to Pt and may be another platinum group element, such as Ru, Rh, Pd, Os or Ir. These materials may be used singly or in a combination of a plurality of them. It is desirable that the diffusion suppressing layer 7 contains any of the materials mentioned above as examples in an amount of 95% or more. However, the diffusion suppressing layer 7 may contain impurities and additives without impairing the effects of the present invention.

The solder layer 8 is a layer to be bonded directly to, for example, a package or the like. In this embodiment, the solder layer 8 is formed of a multilayer film where Au layers 9 and Sn layers 10 are alternately layered. Although the Au layers 9 and the Sn layers 10 may not necessarily be alternately layered in the solder layer 8, the solder layer 8 preferably includes a portion where Au layers 9 and Sn layers 10 are alternately layered, and all the Au layers 9 and all the Sn layers 10 are more preferably alternately layered in the solder layer 8. In this case, when the solder layer 8 is heated, the respective metals in the Au layers 9 and the Sn layers 10 can be more certainly mutually diffused between one and the other of adjacent layers and, thus, the Au layers 9 and the Sn layers 10 can be more certainly alloyed. Hence, in mounting the prism 1 as a film-equipped component on a package or the like, the wettability offered by the adhesion film 3 can be increased and the bonding strength can be more certainly increased.

The Au layers 9 are preferably metal layers containing 95% by mass or more Au. The Sn layers 10 are preferably metal layers containing 95% by mass or more Sn. Depending on the degree of refinement of Au and Sn, impurities, such as Fe or Cr, may be mixed into the metal layers. Therefore, it is desirable that each of the content of Au in the Au-containing metal layers and the content of Sn in the Sn-containing metal layers is 95% by mass or more. Furthermore, Au in the Au layers 9 and Sn in the Sn layers 10 may be alloyed. Alternatively, an Au-Sn layer made of an ally of Au and Sn alloy may be formed at the interface between the Au layer 9 and the Sn layer 10. In the present invention, it is sufficient that the solder layer 8 contains at least one of Au and Sn.

The thickness per layer of the Au layers 9 may be, for example, not less than 10 nm and not more than 1000 nm. The thickness per layer of the Sn layers 10 may be, for example, not less than 10 nm and not more than 1000 nm.

The number of layers of the Au layers 9 may be, for example, not less than 2 and not more than 100. The number of layers of the Sn layers 10 may be, for example, not less than one and not more than 100. The total number of layers of the Au layers 9 and the Sn layers 10 may be, for example, not less than 3 and not more than 200.

The solder layer 8 can be formed by layering each layer, for example, by a vacuum vapor deposition method or a sputtering method. Alternatively, Au and Sn may be alloyed by heating to melting. Still alternatively, the solder layer may be formed by depositing an Au—Sn alloy film by a sputtering method using a target made of Au—Sn alloy. Still alternatively, the solder layer may be formed by depositing an Au—Sn alloy film by a vapor deposition method using Au—Sn alloy as a source of vapor deposition.

In this embodiment, the entire thickness of the solder layer 8 is not particularly limited, but is preferably not less than 1 μm, more preferably not less than 4 μm, preferably not more than 10 μm, and more preferably not more than 6 μm. When the thickness of the solder layer 8 is the above lower limit or more, the wettability offered by the adhesion film 3 in mounting to a package or the like can be increased and the bonding strength can be further increased. When the thickness of the solder layer 8 is the above upper limit or less, each of the layers where their metals are to be mutually diffused in mounting can be further reduced in thickness. Therefore, the Au layers 9 and the Sn layers 10 can be more certainly alloyed in a short period of time and bonding can be certainly achieved in a shorter period of time. In this case, the misalignment of the prism main body 2 in a direction of height can be reduced and, thus, the positional accuracy of the prism 1 as a film-equipped component can be more effectively increased.

The reflective film 4 is provided on the inclined surface 2b of the prism main body 2. The reflective film 4 is formed of, for example, a dielectric multilayer film in which high-refractive index films and low-refractive index films are alternately layered. Examples of the material for the high-refractive index films include TiO₂, Ta₂O₅, ZrO₂, and HfO₂. Examples of the material for the low-refractive index films include SiO₂ and MgF₂. The reflective film 4 may be a monolayer metal film, but the type thereof is not particularly limited. The reflective film 4 is sufficient to be provided at least partially on the inclined surface 2b of the prism main body 2 and may be provided, for example, over the entire inclined surface 2b. When the reflective film 4 is provided on the inclined surface 2b, it can suitably reflect light emitted from a light source. However, the reflective film 4 may not necessarily be provided. Together with the reflective film 4, a dielectric protective film, such as Al₂O₃, SiO₂ or ZrO₂, or an underlying metal film, such as Cr, Ti or Ta, maybe provided. The reflective film 4 can be formed by layering each layer, for example, by a sputtering method or a vacuum vapor deposition method.

Since the prism 1 according to this embodiment has the above structure, the prism 1 can make it less likely that, when subjected to a plurality of component mountings involving heating to melting, any previously mounted component becomes misaligned. This can be explained as follows.

In packaging using a component, such as an optical element, a large number of components have been increasingly mounted in a single package. However, if a solder film containing Au or Sn is used to mount such a component and the mounting of a component is performed a number of times, the solder film for a component mounted in a first mounting may be melted again in second or later mountings, which may cause misalignment of the component mounted in the first mounting.

As a method for solving the above problem, it is conceivable to use solder films having different melting points in decreasing order of melting point. However, this method has a problem of cumbersome material design and thus reduced productivity of the optical device.

In this relation, the Inventors found that when an adhesion film 3 formed of a Ni layer 6, a diffusion suppressing layer 7, and a solder layer 8 layered in this order is heated to melting, cooled, and then heated again, the adhesion film 3 does not melt at a temperature at which it has melted in the first heating and its melting point shifts to a higher temperature. Therefore, when, using this adhesion film 3, the mounting of a component involving heating to melting is performed a number of times, the adhesion film 3 used for any previously mounted component is less likely to melt at a temperature at which the adhesion film 3 for a component to be mounted later is heated to melting in each of processes for mounting components to be mounted later. Hence, any previously mounted component can be less likely to become misaligned in each of processes for mounting components to be mounted later. The reason why the melting point of the component mounted in the first mounting shifts to a higher temperature can be considered as follows.

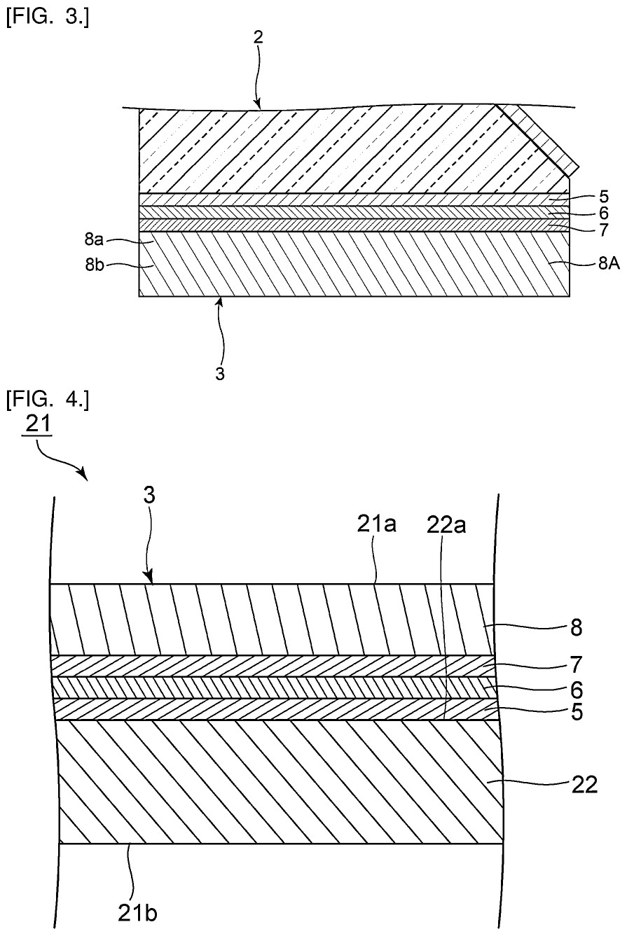

When an adhesion film 3 formed of a Ni layer 6, a diffusion suppressing layer 7, and a solder layer 8 layered in this order is heated to melting, a bonded solder layer 8A is formed as shown in FIG. 3. Like this, a solder layer after being heated to melting may be herein referred to also as a bonded solder layer. The bonded solder layer 8A is normally bonded to an unshown bonding object member.

When the adhesion film 3 formed of a Ni layer 6, a diffusion suppressing layer 7, and a solder layer 8 layered in this order is heated to melting in the above manner, Ni in the Ni layer 6 and the material in the diffusion suppressing layer 7 diffuse into a portion 8a of the bonded solder layer 8A close to the diffusion suppressing layer 7 shown in FIG. 3. In doing so, the bonded solder layer 8A containing Au and Sn forms, as is well known, a mixed crystal composition having a ζ phase rich in Au (Au:Sn=89.24:10.76 (mass ratio)) and a δ phase in which the content of Au and the content of Sn are relatively similar (Au:Sn=62.40:37.60 (mass ratio)), and metal, such as Ni, having permeated the portion 8a of the bonded solder layer 8A close to the diffusion suppressing layer 7 can be thought to diffuse selectively into the δ phase. It can be thought that, as a result, an alloy of the metals in the δ phase and the permeated metal, such as Ni, is formed and, thus, a δ′ phase having a high melting point is formed. In this manner, the bonded solder layer 8A obtained by heating to melting can be thought to form a mixed crystal composition of a ζ phase originally having a high melting point and a δ′ phase obtained by transformation into a higher melting point and be thus increased in melting point as a whole. It can be thought that, in the bonded solder layer 8A obtained by heating to melting, much of the δ′ phase is formed in the portion 8a close to the diffusion suppressing layer 7 and much of the ζ phase is formed from the central portion 8b of the bonded solder layer 8 to the outer portion beyond the central portion 8b.

Therefore, in the bonded solder layer 8A obtained by heating to melting, the mass ratio (Au:Sn) of the portion 8a of the bonded solder layer 8A close to the diffusion suppressing layer 7 in a direction of thickness of the bonded solder layer 8A is preferably in a range of 40:60 to 71:29 and more preferably in a range of 55:45 to 65:35. On the other hand, the mass ratio (Au:Sn) of the central portion 8b of the bonded solder layer 8A is preferably in a range of 84:16 to 94:6 and more preferably in a range of 88:12 to 92:8.

In this embodiment, the ratio of the thickness of the Ni layer 6 to the thickness of the diffusion suppressing layer 7 (thickness of the Ni layer 6 to thickness of the diffusion suppressing layer 7) is preferably not less than 1, more preferably not less than 5, still more preferably not less than 10, preferably not more than 600, more preferably not more than 500, even more preferably not more than 400, even still more preferably not more than 300, even yet still more preferably not more than 200, even yet still more preferably not more than 100, even yet still more preferably not more than 80, even yet still more preferably not more than 50, even yet still more preferably not more than 30, even yet still more preferably not more than 20, and even yet still more preferably not more than 15. When the ratio (thickness of the Ni layer 6 to thickness of the diffusion suppressing layer 7) is in the above range, the amount of Ni diffused into the bonded solder layer 8A can be further increased. Therefore, when a plurality of component mountings involving heating to melting are performed, any previously mounted component can be even less likely to become misaligned. Here, when the underlying metal layer 5 is Ni, the thickness of the Ni layer 6 includes the thickness of the underlying metal layer 5.

The thickness of the Ni layer 6 is preferably not less than 200 nm, more preferably not less than 300 nm, even more preferably not less than 400 nm, even still more preferably not less than 500 nm, even yet still more preferably not less than 800 nm, even yet still more preferably not less than 1000 nm, even yet still more preferably not less than 1500 nm, even yet still more preferably not less than 2000 nm, preferably not more than 6000 nm, and more preferably not more than 3000 nm. When the thickness of the Ni layer 6 is the above lower limit or more, the amount of Ni diffused into the bonded solder layer 8A can be further increased. Therefore, even when a plurality of component mountings involving heating to melting are performed, any previously mounted component can be even less likely to become misaligned. When the thickness of the Ni layer 6 is the above upper limit or less, the meltability of the solder layer 8 in the first heating to melting can be further increased. Here, when the underlying metal layer 5 is Ni, the thickness of the Ni layer 6 includes the thickness of the underlying metal layer 5.

The thickness of the diffusion suppressing layer 7 is preferably not less than 10 nm, more preferably not less than 20 nm, even more preferably not less than 30 nm, even still more preferably not less than 40 nm, even yet still more preferably not less than 50 nm, even yet still more preferably not less than 60 nm, even yet still more preferably not less than 70 nm, even yet still more preferably not less than 80 nm, even yet still more preferably not less than 90 nm, even yet still more preferably not less than 100 nm, even yet still more preferably more than 100 nm, even yet still more preferably not less than 110 nm, even yet still more preferably not less than 120 nm, even yet still more preferably not less than 140 nm, even yet still more preferably not less than 150 nm, even yet still more preferably not less than 160 nm, even yet still more preferably not less than 180 nm, even yet still more preferably not less than 200 nm, even yet still more preferably not less than 220 nm, even yet still more preferably not less than 240 nm, even yet still more preferably not less than 250 nm, preferably not more than 1000 nm, more preferably not more than 950 nm, even more preferably not more than 900 nm, even still more preferably not more than 850 nm, even yet still more preferably not more than 800 nm, even yet still more preferably not more than 750 nm, even yet still more preferably not more than 700 nm, even yet still more preferably not more than 650 nm, even yet still more preferably not more than 600 nm, even yet still more preferably not more than 550 nm, even yet still more preferably not more than 500 nm, even yet still more preferably not more than 450 nm, even yet still more preferably not more than 400 nm, even yet still more preferably not more than 350 nm, and even yet still more preferably not more than 300 nm.

When the thickness of the diffusion suppressing layer 7 is the above lower limit or more, excessive diffusion of Ni into the solder layer 8 can be suppressed and, thus, the meltability of the solder layer 8 in the first heating to melting can be further increased. Particularly, when Au and Sn are contained in the solder layer 8, a change in melting temperature attributed to overreaction of Au and Sn in the solder layer 8 to Ni can be effectively reduced. Thus, the melting peak in the first heating to melting can be made sharper and, thus, the meltability of the solder layer 8 can be further increased.

When the thickness of the diffusion suppressing layer 7 is the above upper limit or less, the amount of Ni diffused into the bonded solder layer 8A can be further increased. Therefore, even when a plurality of component mountings involving heating to melting are performed following the first component mounting, any previously mounted component can be even less likely to become misaligned. Particularly, when Au and Sn are contained in the solder layer 8, a change in melting temperature attributed to reaction of Au and Sn in the solder layer 8 to Ni occurs. Therefore, by appropriately adjusting the amount of Ni diffused into the bonded solder layer 8A, remelting of the bonded solder layer 8A during the second or later heating to melting can be more certainly suppressed. In the case where a platinum group element is selected as the material for the diffusion suppressing layer 7, the thickness of the diffusion suppressing layer 7 is preferably the above upper limit or less from the viewpoint of cost reduction.

In the case where a plurality of component mountings involving heating to melting are performed, the prism 1 according to this embodiment, even when used as a component to be mounted previously, is less likely to become misaligned in the process for mounting a component to be mounted later. Therefore, the prism 1 according to this embodiment can increase the reliability of the optical device.

Furthermore, since there is no need to use solder films having different melting points, the material design can be easily made and, therefore, the productivity of the optical device can be increased.

### Second Embodiment

FIG. 4 is a schematic cross-sectional view showing a film-equipped component according to a second embodiment of the present invention.

A sub-mount 21 is a film-equipped component for use in an optical device or an electronic device. In this embodiment, the sub-mount 21 is a sub-mount for an optical element. Particularly, the sub-mount 21 is a sub-mount having a heatsink function. However, the sub-mount 21 may be a sub-mount for an element other than the optical element, a sub-mount for an optical device component, such as a prism or a lens, or a sub-mount for an electronic component.

The sub-mount 21 includes a substrate 22 as a component main body and an adhesion film 3. The adhesion film 3 is provided on a principal surface 22a of the substrate 22. The same adhesion film as in the first embodiment may be used as the adhesion film 3.

The substrate 22 has the shape of an approximately rectangular plate. However, the substrate 22 may have, for example, an approximately disc shape and the shape thereof is not particularly limited.

The material for the substrate 22 is not particularly limited, but the substrate 22 is preferably made of a highly heat-dissipative material. Examples of the material for the substrate 22 include a metallic material, a ceramic material, a carbon material, and a composite material of them. These materials may be used singly or in a combination of a plurality of them. Specifically, examples of the metallic material include Cu, Al, Ag, W, Mo, CuW, and CuMo. Examples of the ceramic material include AlN, Si₃N₄, SiC, and Al₂O₃. Examples of the carbon material include graphite and diamond. Among composite materials, examples of a mixed material include Cu-diamond, Ag-diamond, Al—SiC, and Mg—SiC. Among composite materials, examples of a material having a layered structure include Cu/AlN/Cu, Cu/Si₃N₄/Cu, Cu/Mo/Cu, and Cu/graphite/Cu. These materials may be used singly or in a combination of different material or different structures.

The thickness of the substrate 22 is not particularly limited, but is preferably not less than 0.1 mm, more preferably not less than 0.2 mm, preferably not more than 1.0 mm, and more preferably not more than 0.5 mm. When the thickness of the substrate 22 is the above lower limit or more, the heat dissipation can be further increased. When the thickness of the substrate 22 is the above upper limit or less, the optical device in which the substrate 22 is used can be further reduced in height.

Depending on the material for the substrate 22, the underlying metal layer 5 may be dispensed with. The rest is the same as in the first embodiment.

Since also the sub-mount 21 is formed of the Ni layer 6, the diffusion suppressing layer 7, and the solder layer 8 layered in this order, the sub-mount 21 can make it less likely that, when subjected to a plurality of component mountings involving heating to melting, any previously mounted component becomes misaligned.

### Third Embodiment

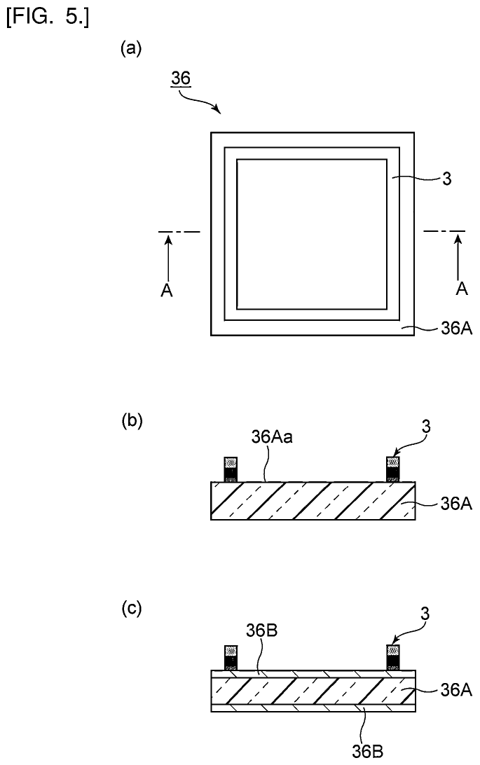

FIG. 5(a) is a schematic plan view showing a film-equipped component according to a third embodiment of the present invention and FIG. 5(b) is a schematic cross-sectional view of a portion taken along the line A-A of FIG. 5(a).

A lid 36 is, as will be described hereinafter, a film-equipped component for use in an optical device or an electronic device. In this embodiment, the lid 36 is a lid 36 for an optical element. However, the lid 36 may be a lid 36 for an element other than the optical element, a lid 36 for an electronic component or a lid 36 for a package in which an optical element or an electronic element is contained.

The lid 36 includes a member 36A as a component main body and an adhesion film 3. The adhesion film 3 is provided on the side 36Aa of the member 36A to be brought into contact with a package. The same adhesion film as in the first embodiment may be used as the adhesion film 3. The location of the adhesion film 3 is not particularly limited, but may be, for example, a portion of the member 36A to be brought into contact with the package as shown in FIG. 5(b). Alternatively, the adhesion film 3 may be provided on a functional film 36B to be described hereinafter.

The member 36A has the shape of an approximately rectangular plate. However, the member 36A may have, for example, an approximately disc shape and the shape thereof is not particularly limited.

The material for the member 36A is not particularly limited and can be appropriately selected according to the intended use. For example, when much weight is given to the transmittance, the member 36A is preferably made of a highly light transmissive material. Specifically, examples of the material for the member 36A that can be used include sapphire, silicon wafer, and glass. Examples of the glass include optical glasses, such as borosilicate-based glass and quartz. On the other hand, when much weight is given to the heat dissipation, the material for the member 36A is preferably a highly heat-dissipative material. In this case, the above-described material for the substrate 22 in the second embodiment may be used as the material for the member 36A. As shown as a modification in FIG. 5(c), the member 36A may be further provided with functional films 36B, such as a reflective film, an antireflection film, and an antifouling film. The same reflective film as in the first embodiment may be used as the reflective film. An example of the antireflection film that can be used is a dielectric multilayer film in which high-refractive index films and low-refractive index films are alternately layered. Examples of the material for the high-refractive index films that can be used include Ta₂O₅, TiO, TiO₂, Nb₂O₅, HfO₂, ZrO₂, and Si. Examples of the material for the low-refractive index films that can be used include SiO, SiO₂, and MgF₂. Other than the above materials, a material for a medium-refractive index film may be used. For example, Al₂O₃ may be used as the material for a medium-refractive index film. An example of the antifouling film is a fluorine coating. The location of the functional film 36B is not particularly limited, but may be, for example, the front surface and/or back surface of the member 36A as shown in FIG. 5(c).

The thickness of the member 36A is not particularly limited, but is preferably not less than 0.1 mm, more preferably not less than 0.2 mm, preferably not more than 2.0 mm, and more preferably not more than 1.0 mm. When the thickness of the member 36A is the above lower limit or more, the heat dissipation can be further increased. In addition, the device in which the member 36A is used can be increased in strength. When the thickness of the member 36A is the above upper limit or less, the device in which the member 36A is used can be further reduced in height.

Depending on the material for the member 36A, the underlying metal layer 5 may be dispensed with. The rest is the same as in the first embodiment.

Since also the lid 36 is formed of the Ni layer 6, the diffusion suppressing layer 7, and the solder layer 8 layered in this order, the lid 36 can make it less likely that, when subjected to a plurality of component mountings involving heating to melting, any previously mounted component becomes misaligned.

In the first, second, and third embodiments, the prism 1, the sub-mount 21, and the lid 36 have been described as the film-equipped components. However, the film-equipped component according to the present invention may be a lens, an optical element or a package member for use in mounting an optical element and is not particularly limited. The film-equipped component can be widely used as a component for an optical device or an electronic component.

### Optical Device

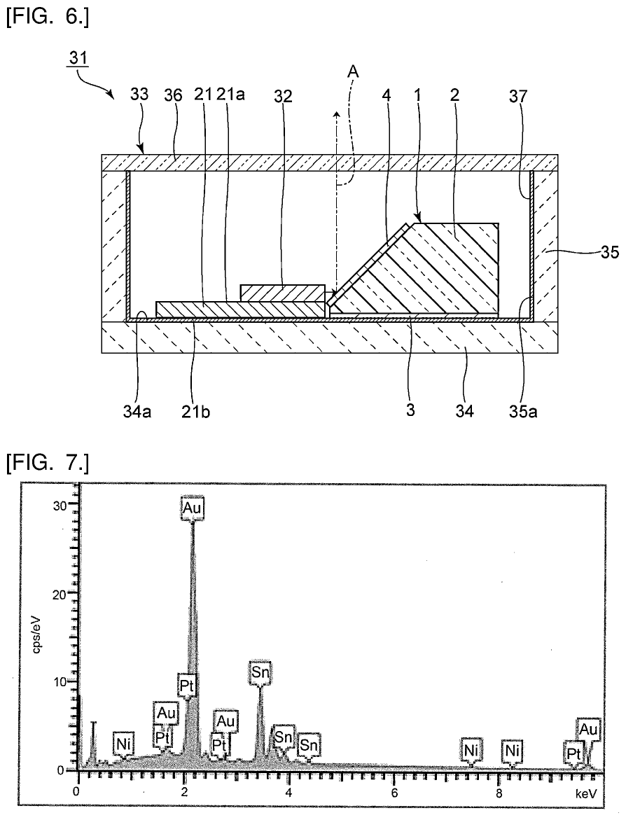

FIG. 6 is a schematic cross-sectional view showing an optical device according to an embodiment of the present invention. As shown in FIG. 6, an optical device 31 includes an optical element 32, a sub-mount 21, a prism 1, and a package 33. The package 33 contains the optical element 32, the sub-mount 21, and the prism 1.

More specifically, the package 33 is a container-shaped member having a bottom portion 34 and a sidewall portion 35 disposed on the bottom portion 34. The package 33 can be made of, for example, a ceramic material. Examples of the ceramic material that can be used include alumina and aluminum nitride. Among them, aluminum nitride is preferred from the viewpoint of further increasing the heat dissipation.

The bottom portion 34 has a mounting surface 34a. The sidewall portion 35 has an interior surface 35a. A metal film 37 is provided on the mounting surface 34a of the bottom. portion 34 and the interior surface 35a of the sidewall portion 35.

In this embodiment, the optical element 32 and the prism 1 are arranged on a portion of the metal film 37 located on the top of the mounting surface 34a. More specifically, the sub-mount 21 is provided on the metal film 37 and the optical element 32 is disposed on the sub-mount 21. In doing so, one principal surface 21a of the sub-mount 21 is bonded by an unshown adhesion film 3 to the optical element 32. The other principal surface 21b of the sub-mount 21 is also bonded by an unshown adhesion film 3 to the metal film 37. The prism 1 is also bonded by the adhesion film 3 to the metal film 37.

The package 33 may not necessarily include the metal film 37. However, the package 33 preferably includes the metal film 37 as with this embodiment.

The metal film 37 is preferably an Au film. In this case, the metal film 37 is less likely to be oxidized and, therefore, the bonding strength between each of the sub-mount 21 and the prism 1 and the package 33 can be further increased in producing an optical device 31.

In this embodiment, the metal film 37 is provided over the entire mounting surface 34a of the bottom. portion 34 and the entire interior surface 35a of the sidewall portion 35 of the package 33. However, the metal film 37 is sufficient to be provided at least on a portion where the sub-mount 21 and the prism 1 are disposed.

A lid 36 is provided on the top of the sidewall portion 35 of the package 33 to encapsulate the optical element 32 and the prism 1. The type of the lid 36 is not particularly limited, but is a glass lid in this embodiment. The lid 36 and the sidewall portion 35 are bonded together by an unshown adhesion film 3. In this case, no gas is produced after the bonding. Therefore, impurities are less likely to adhere to the reflective film 4 of the prism 1 and, thus, the reflection characteristics are less likely to be deteriorated. Furthermore, when a plurality of component mountings involving heating to melting are performed, any previously mounted component can be even less likely to become misaligned.

In this embodiment, the optical element 32 is a light source that emits light to the prism 1. The type of the light source is not particularly limited and examples that can be used include an LD and an LED. As shown in FIG. 6, light A having exited the optical element 32 is reflected by the prism 1, passes through the lid 36, and is then emitted to the outside of the optical device 31. The optical element 32 may be a light-receiving element that receives light from the prism 1.

The sub-mount 21 is provided in order that the optical element 32 is mounted thereon. Furthermore, the sub-mount 21 serves also as a heatsink. Therefore, heat produced by the optical element 32 can be efficiently dissipated through the sub-mount 21 to the package 33.

In the optical device 31, the prism 1 and the package 33 are bonded together by the adhesion film 3 of the prism 1. Furthermore, the optical element 32 and the sub-mount 21 are bonded together by the adhesion film 3 of the sub-mount 21.

Therefore, for example, after the optical element 32 is mounted by the adhesion film 3 of the sub-mount 21 on the sub-mount 21 and the prism 1 is mounted by the adhesion film 3 of the prism 1 on the bottom portion 34, the prism 1 is less likely to be misaligned in the direction of height by heating during bonding of the optical element 32 and the sub-mount 21 to the bottom portion 34 by an adhesion film 3. Thus, the optical device 31 can be increased in reliability.

As with this embodiment, an adhesion film 3 may be further provided on the other principal surface 21b of the sub-mount 21 to bond the sub-mount 21 and the package 33 together by the adhesion film 3. Furthermore, the sidewall portion 35 of the package 33 may be provided with an adhesion film 3 to bond the sidewall portion 35 to the lid 36 by the adhesion film 3.

The temperature in bonding the optical element 32, the sub-mount 21, and the prism 1 may be, for example, 280° C. to 300° C. The temperature in bonding the lid 36 and the sidewall portion 35 may be 280° C. to 340° C. By bonding them in the above temperature ranges, the positional accuracy of the optical element 32, the sub-mount 21, and the prism 1 in the direction of height can be further increased.

The present invention will be described below in further detail with reference to specific examples. The present invention is not at all limited by the following examples and modifications and variations may be appropriately made therein without changing the gist of the invention.

### EXAMPLE 1

A 100-nm thick Cr film (underling metal film 5) was deposited on a glass substrate (item number “BDA” manufactured by Nippon Electric Glass Co., Ltd., thickness: 0.5 mm) by sputtering. Next, a 1000-nm thick Ni film (Ni layer 6) was deposited on the obtained Cr film by sputtering. Next, a 250-nm thick Pt film (diffusion suppressing layer 7) was deposited on the obtained Ni film by sputtering. Finally, a solder layer 8 was formed by alternately layering Au layers 9 and Sn layers 10 to a total of 91 layers by vacuum vapor deposition, thus obtaining a film-equipped component. In doing so, the thickness per layer of the Au layers 9 was 50 nm. The thickness per layer of the Sn layers 10 was 47 nm. The mass ratio (Au:Sn) between Au and Sn was 76:24 to 80:20.

### EXAMPLE 2

A film-equipped component was obtained in the same manner as in Example 1 except that the Ni film was deposited to have a thickness of 250 nm.

### EXAMPLE 3

A film-equipped component was obtained in the same manner as in Example 1 except that the Pt film was deposited to have a thickness of 50 nm.

### EXAMPLE 4

A film-equipped component was obtained in the same manner as in Example 1 except that the Pt film was deposited to have a thickness of 500 nm.

### EXAMPLE 5

A film-equipped component was obtained in the same manner as in Example 1 except that the Pt film was deposited to have a thickness of 1000 nm.

### COMPARATIVE EXAMPLE 1

A film-equipped component was obtained in the same manner as in Example 1 except that no Ni film was deposited.

### REFERENCE EXAMPLE 1

A film-equipped component was obtained in the same manner as in Example 1 except that no Pt film was deposited.

### Evaluations

### (Elemental Analysis)

The film-equipped component obtained in Example 1 was subjected to heat treatment at 330° C. for one minute. The film-equipped component after the heat treatment underwent elemental analysis by energy dispersive X-ray spectroscopy (SEM-EDX). Devices used for the SEM-EDX measurement were an FE-SEM (field-emission scanning electron microscope, model number “SU8220” manufactured by Hitachi High-Tech Corporation) and an EDX (energy dispersive X-ray spectrometer, model number “EMAX Evolution EX-370 X-Max150” manufacture by Horiba, Ltd.).

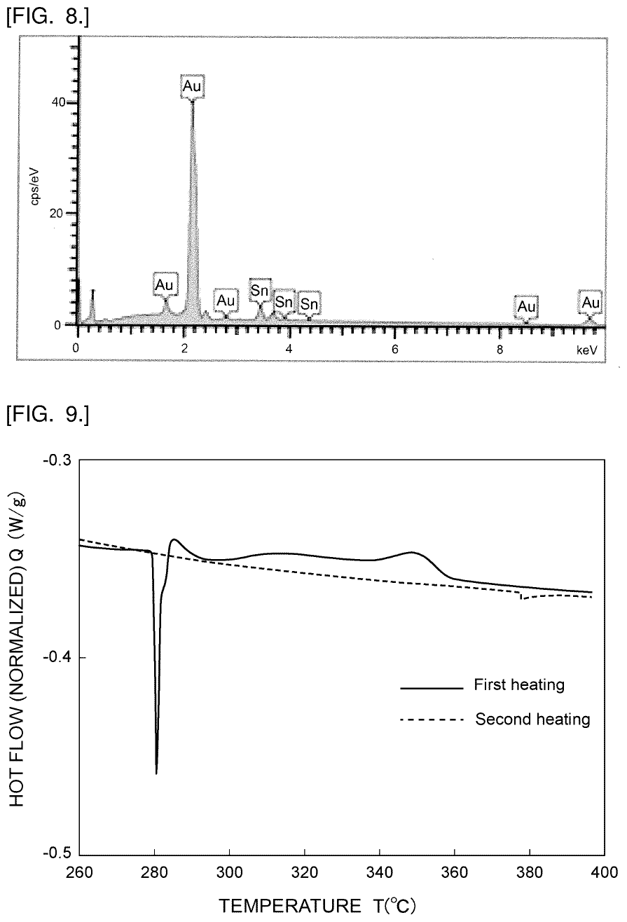

FIG. 7 is a graph showing an EDX spectrum of a portion of a bonded solder layer close to a diffusion suppressing layer in a film-equipped component obtained in Example 1. FIG. 8 is a graph showing an EDX spectrum of a central portion of the bonded solder layer in the film-equipped component obtained in Example 1. In each of the EDX spectra, observation peaks other than those of Au, Sn, Pt, and Ni are due to measurement jigs and the like. The above-mentioned portion of the bonded solder layer close to the diffusion suppressing layer refers to the portion 8a of the bonded solder layer 8A close to the diffusion suppressing layer 7 in FIG. 3. The above-mentioned central portion of the bonded solder layer refers to the central portion 8b of the bonded solder layer 8A in FIG. 3.

According to FIG. 7, the composition of the portion of the bonded solder layer close to the diffusion suppressing layer was 59% by mass Au, 33% by mass Sn, 1% by mass Ni, and 7% by mass Pt. Therefore, it was found from. FIG. 7 that Ni and Pt diffused into the portion of the bonded solder layer close to the diffusion suppressing layer.

According to FIG. 8, the composition of the central portion of the bonded solder layer was 90% by mass Au and 10% by mass Sn. Therefore, it was found from FIG. 8 that the central portion of the bonded solder layer had a larger content of Au than the portion close to the diffusion suppressing layer and formed a ζ phase.

### (DSC Measurement)

The film-equipped components (not subjected to heat treatment) obtained in Examples 1 to 5, Comparative Example 1, and Reference Example 1 were subjected to differential scanning calorimetry (DSC measurement). A differential scanning calorimeter (item number “DSC 2500” manufactured by TA Instruments) was used for DSC measurement and the measurement was conducted under conditions of a temperature of 25° C. to 400° C. and a rate of temperature increase/decrease of 20° C./min.

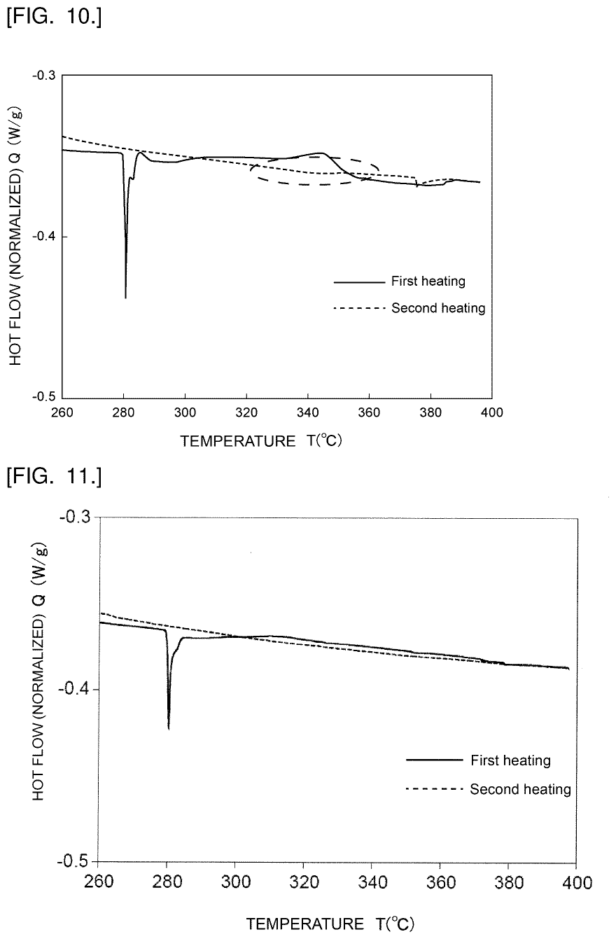

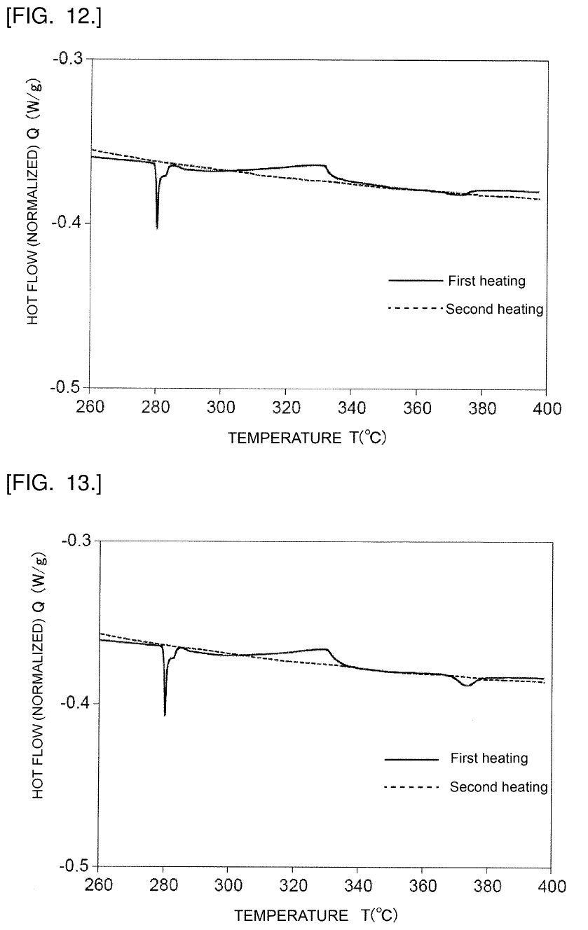

FIGS. 9 to 15 are respective differential scanning calorimetry results of the film-equipped components produced in Examples 1 to 5, Comparative Example 1, and Reference Example 1 and show the respective results in this order.

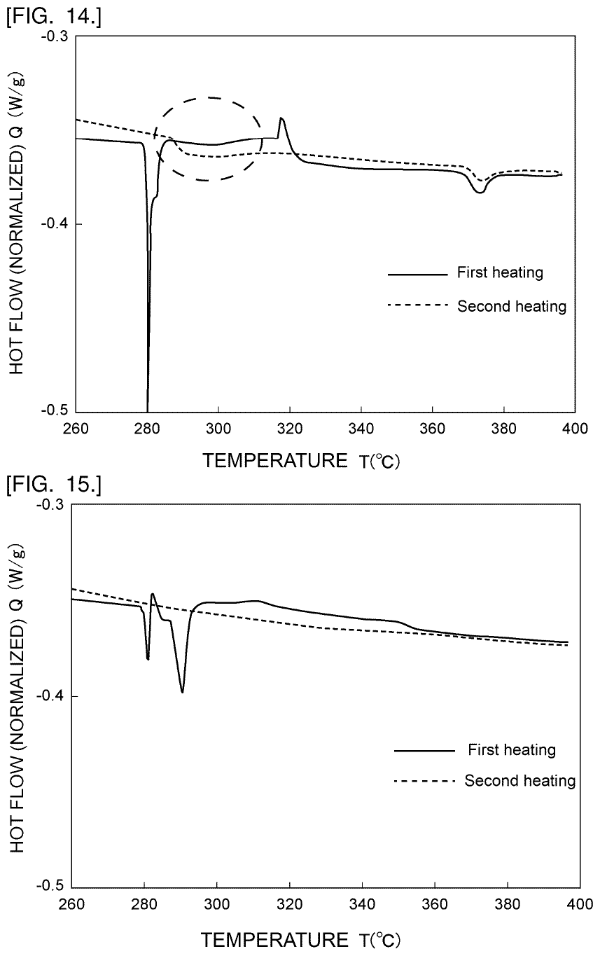

FIGS. 9 to 13 show that, in the film-equipped components obtained in Examples 1 to 5, the melting peak observed in the first heating disappeared in the second heating. Furthermore, it is shown that in Example 1 the melting peak more certainly disappeared in the second heating as compared to Example 2. This can be considered to show an effect of the ratio of the thickness of the Ni layer to the thickness of the diffusion suppressing layer (thickness of the Ni layer to thickness of the diffusion suppressing layer). Furthermore, it can be seen from Examples 3 to 5 that, in the presence of a 1000-nm thick Ni film, the melting behavior similar to that in Example 1 was exhibited in a thickness range of the Pt film of 50 nm to 1000 nm. According to FIG. 14, in Comparative Example 1, unlike the above examples, the melting peak observed in the first heating was confirmed also in the second heating.

These results show that, in the film-equipped components obtained in Examples 1 to 5, their solder layers were transformed into higher melting points by heating to melting in the first heating. In Reference Example 1, two melting peaks were observed in the first heating process. The reason for this can be that since no diffusion suppressing layer was provided, Ni excessively diffused into the solder layer during the first melting and, as a result, the solder layer became less likely to be melted.

It was confirmed from the above that the film-equipped components obtained in Examples 1 to 5 can make it less likely that, when subjected to a plurality of component mountings involving heating to melting, any previously mounted component becomes misaligned.

### REFERENCE SIGNS LIST

1 . . . prism
2 . . . prism main body
2a . . . bottom surface
2b . . . inclined surface
2c . . . top surface
3 . . . adhesion film
4 . . . reflective film
5 . . . underlying metal layer
6. . . . Ni layer
7 . . . diffusion suppressing layer
8 . . . solder layer
8A . . . bonded solder layer
8a . . . portion close to diffusion suppressing layer
8b . . . central portion
9. . . . Au layer
10. . . . Sn layer
21 . . . sub-mount
21a . . . one principal surface
21b . . . the other principal surface
22 . . . substrate
22a . . . principal surface
31 . . . optical device
32 . . . optical element
33 . . . package
34 . . . bottom portion
34a . . . mounting surface
35 . . . sidewall portion
35a . . . interior surface
36 . . . lid
36A . . . member
36Aa . . . side to be brought into contact with package
36B . . . functional film
37 . . . metal film

1. A film-equipped component comprising:
a component main body having a principal surface; and
an adhesion film provided on the principal surface of the component main body,
the adhesion film comprising:
a Ni layer layered directly or indirectly on the principal surface of the component main body and containing Ni;
a diffusion suppressing layer provided on the Ni layer; and
a solder layer provided on the diffusion suppressing layer and containing at least one of Au and Sn.

2. The film-equipped component according to claim 1, wherein a ratio of a thickness of the Ni layer to a thickness of the diffusion suppressing layer (thickness of Ni layer to thickness of diffusion suppressing layer) is not less than 1 and not more than 600.

3. The film-equipped component according to claim 1, wherein the diffusion suppressing layer contains at least one selected from the group consisting of Ru, Rh, Pd, Os, Ir, and Pt.

4. The film-equipped component according to claim 1, wherein the diffusion suppressing layer contains Pt.

5. The film-equipped component according to claim 1, wherein the diffusion suppressing layer has a thickness of 1000 nm or less.

6. The film-equipped component according to claim 1, wherein
the solder layer is bonded to a bonding object member to form a bonded solder layer, and
in a direction of thickness of the bonded solder layer,
a mass ratio (Au:Sn) between Au and Sn in a portion of the bonded solder layer close to the diffusion suppressing layer is 40:60 to 71:29 and
a mass ratio (Au: Sn) between Au and Sn in a central portion of the bonded solder layer is 84:16 to 94:6.

7. The film-equipped component according to claim 1, wherein
the solder layer is bonded to a bonding object member to form a bonded solder layer, and
the bonded solder layer is composed of a region containing Au and Sn as major ingredients, a region containing Pt as a major ingredient, and a region containing Ni as a major ingredient in order closer to the bonding object member in a direction of thickness of the bonded solder layer.

8. The film-equipped component according to claim 1, wherein
the solder layer is bonded to a bonding object member to form a bonded solder layer, and
Ni is diffused into the bonded solder layer.

9. The film-equipped component according to claim 8, wherein
the solder layer is bonded to a bonding object member to form a bonded solder layer, and
a content of Ni in the bonded solder layer has a concentration gradient in a direction of thickness of the bonded solder layer.

10. The film-equipped component according to claim 1, being at least one selected from the group consisting of a prism, a lens, an optical element, a sub-mount for use in mounting the optical element, a package for use in mounting the optical element, and a lid.

11. An optical device comprising:
a prism;
an optical element that emits or receives light to or from the prism;
a package where the prism and the optical element are mounted; and
a sub-mount provided between the optical element and the package,
at least one of the prism and the sub-mount being the film-equipped component according to claim 1.
